(19) United States
(12) Patent Application Publication
(10) Pub. No.: US 2026/0246461 A1
(43) Pub. Date: Aug. 20, 2026

(54) SEMICONDUCTOR MODULE

(71) Applicant: Honda Motor Co., Ltd., Tokyo (JP)

(72) Inventors: Daishi NAGAI, Tokyo (JP); Hironori IDOGAWA, Tokyo (JP); Toshiyuki UEMORI, Tokyo (JP)

(73) Assignee: Honda Motor Co., Ltd., Tokyo (JP)

(21) Appl. No.: 19/398,069

(22) Filed: Nov. 24, 2025

(30) Foreign Application Priority Data
Feb. 18, 2025 (CN) 202510175085.5

(51) Int. Cl. H03K 17/12; H03K 17/14

(52) U.S. Cl. CPC H03K 17/127; H03K 17/14; H03K 2217/0027; H03K 2217/0036

(57) ABSTRACT

Provided is a semiconductor module capable of ensuring current capacity by adopting bipolar chips to reduce cost. The semiconductor module includes a first switch element area, a second switch element area, and a third switch element area. The first switch element area and the third switch element area are configured in a manner of sandwiching the second switch element area. A first switching element, a second switching element, and a third switching element are respectively disposed in the first switch element area, the second switch element area, and the third switch element area. The first switching element, the second switching element, and the third switching element are sequentially connected in series. The second switching element has a bipolar chip and a unipolar chip connected in parallel.

### CROSS-REFERENCE TO RELATED APPLICATION

This application claims the priority benefit of China application serial no. 202510175085.5, filed on February 18, 2025. The entirety of the above-mentioned patent application is hereby incorporated by reference herein and made a part of this specification.

### BACKGROUND

### Technical Field

The disclosure relates to a semiconductor module, and particularly relates to a semiconductor module having a bipolar chip.

### Related Art

In recent years, in order to ensure access to more affordable, reliable, sustainable and advanced energy for more people, research and development related to charging power supply for vehicles equipped with secondary batteries that contribute to energy efficiency is being conducted.

In technology related to charging power supply for vehicles equipped with secondary batteries, a high-voltage battery connection switching system uses merely one type of chip (for example, unipolar components represented by silicon carbide (SiC)) to design operations for switching output voltage between series connection and parallel connection of batteries (switching operation, belonging to high efficiency operation), general operation (constant conduction, belonging to high efficiency operation), or heat operation (switching operation/constant conduction, belonging to low efficiency operation). High efficiency operation or low efficiency operation is required depending on different situations. However, it is difficult to have both operation modes simultaneously with merely one type of chip.

When power supplies are in series, the switching element area have to be able to carry large current, so multiple chips are required to ensure current capacity, resulting in increased cost.

Furthermore, no temperature detector is provided in high-cost wide bandgap unipolar components, so it is difficult to grasp the temperature of the entire chip using a separate thermistor.

### SUMMARY

Given the above aspects, the disclosure adopts bipolar chips to ensure current capacity in order to solve the described problems, with the purpose of achieving cost reduction, and moreover, further helps with energy efficiency.

In order to achieve the described purpose, the disclosure is a semiconductor module including a first switch element area, a second switch element area, and a third switch element area. The first switch element area and the third switch element area are configured in a manner of sandwiching the second switch element area. A first switching element, a second switching element, and a third switching element are respectively disposed in the first switch element area, the second switch element area, and the third switch element area. The first switching element, the second switching element, and the third switching element are sequentially connected in series. The second switching element has a bipolar chip and a second unipolar chip connected in parallel.

According to the structure, adopting bipolar chips to ensure current capacity may reduce cost.

Based on the above, the semiconductor module of the disclosure may employ bipolar chips to ensure current capacity, and may simultaneously possess both high efficiency and low efficiency operation modes, achieving the purpose of cost reduction, thereby helping improve energy efficiency.

To make the foregoing features and advantages of the disclosure more comprehensible, embodiments are specifically provided below and described in detail in conjunction with the accompanying drawings as follows.

### BRIEF DESCRIPTION OF THE DRAWINGS

FIG. 1 shows a schematic diagram of a semiconductor module according to an embodiment of the disclosure.

FIG. 2 shows a partial circuit diagram of a power supply according to an embodiment of the disclosure.

FIG. 3A to FIG. 3D show operation diagrams of the semiconductor module when the power supply enters a heat generation mode according to an embodiment of the disclosure.

### DESCRIPTION OF THE EMBODIMENTS

In one embodiment of the disclosure, the first switching element and the third switching element respectively have a first unipolar chip and a third unipolar chip. The first unipolar chip and the third unipolar chip are configured in a manner of sandwiching the second switching element.

In one embodiment of the disclosure, the second unipolar chip of the second switching element is configured to be point-symmetric or line-symmetric with reference to the bipolar chip.

In one embodiment of the disclosure, the first switch element area and the third switch element area are disposed to be adjacent to the bipolar chip of the second switching element.

According to the structure, by disposing the bipolar chip with large heat generation to be adjacent to other switch element areas, temperature rise when the second switching element generates heat may be suppressed.

In one embodiment of the disclosure, the bipolar chip of the second switching element includes a temperature detection part for detecting component temperature.

According to the structure, the bipolar chip capable of detecting temperature is placed in the center, facilitating detection of the temperature of the unipolar chips.

In one embodiment of the disclosure, the second switch element area is divided into at least two split areas. The first switch element area is configured to sandwich one of the at least two split areas, and the third switch element area is configured to sandwich the other one of the at least two split areas.

According to the structure, when the second switching element generates a large amount of heat, the thermal load is dispersed and cooling performance is improved. Furthermore, even when the first switching element and the third switching element generate heat, the thermal load is dispersed and cooling performance is improved.

In one embodiment of the disclosure, one of the at least two split areas and the other one of the at least two split areas respectively have independent gate drive circuits.

According to the structure, when it is desired to make the first switching element and the second switching element conduct or make the second switching element and the third switching element conduct to accelerate heat generation, by concentrating the thermal load, operation may be performed in a temperature range that generates more heat.

In one embodiment of the disclosure, the semiconductor module has a first heat generation mode and a second heat generation mode. The first heat generation mode causes the first switching element and the second switching element to conduct, and the second heat generation mode causes the second switching element and the third switching element to conduct.

According to the structure, when used in heat generation mode, heat generation regions may be placed close together, thereby enabling operation in a temperature range where heat generation is more easily produced.

Reference will now be made in detail to exemplary embodiments of the disclosure, examples of which are illustrated in the accompanying drawings. Wherever possible, the same reference numerals will be used throughout the drawings and the description to refer to the same or like parts.

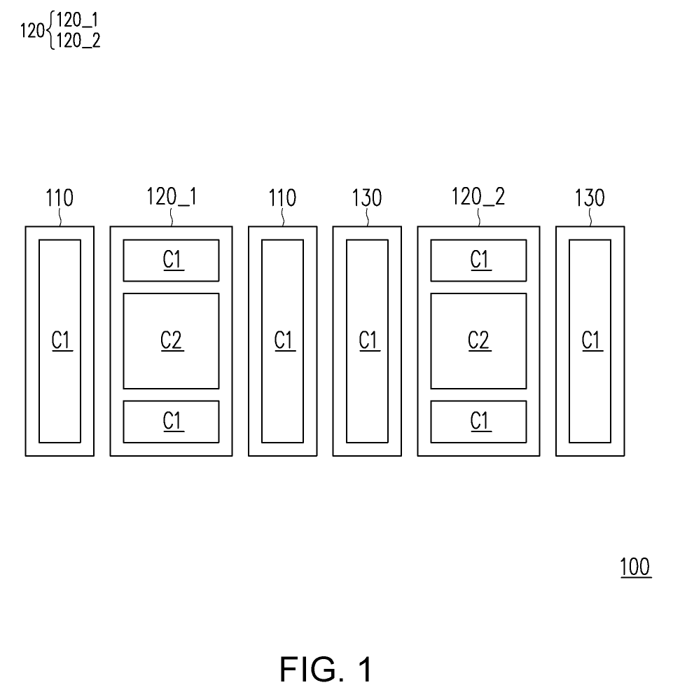

FIG. 1 shows a schematic diagram of a semiconductor module according to an embodiment of the disclosure. Referring to FIG. 1, a semiconductor module 100 may be applied to, for example, a switching circuit in a power supply. The semiconductor module 100 includes a first switch element area 110, a second switch element area 120, and a third switch element area 130. The first switch element area 110 and the third switch element area 130 are configured in a manner of sandwiching the second switch element area 120. As shown in FIG. 1, the second switch element area 120 may be divided into two split areas 120_1 and 120_2, the first switch element area 110 is configured to sandwich the split area 120_1, and the third switch element area 130 is configured to sandwich the split area 120_2. The split areas 120_1 and 120_2 may respectively have independent gate drive circuits. In this embodiment, the first switch element area 110 and the third switch element area 130 are formed by silicon carbide chips C1 (unipolar chips), and the split areas 120_1 and 120_2 are formed by silicon carbide chips C1 and Insulated Gate Bipolar Transistor (IGBT) chips C2 (bipolar chips), but the disclosure is not limited thereto. The insulated gate bipolar transistor chip C2 may be provided with a reverse conducting diode as needed. Each area may also be divided into multiple dies as needed. The material of the die is exemplified by silicon carbide, but known materials such as silicon, gallium nitride, and diamond may also be used.

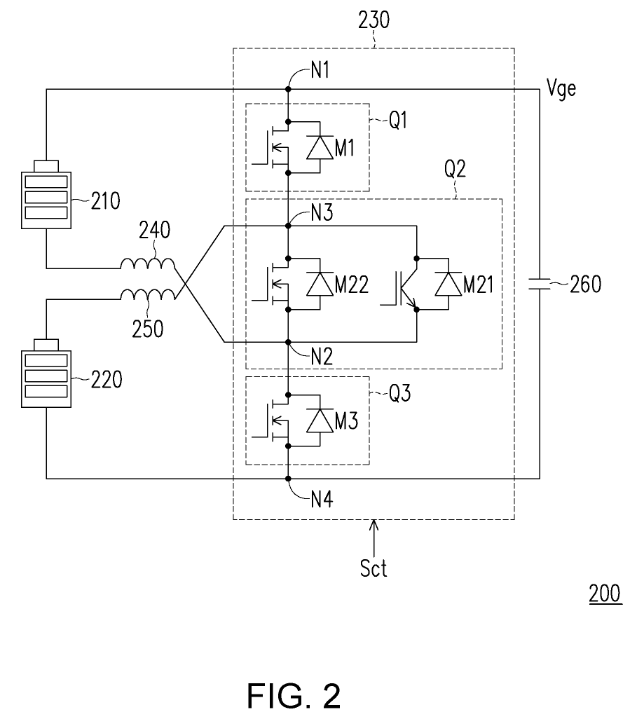

FIG. 2 shows a partial circuit diagram of a power supply according to an embodiment of the disclosure. A power supply 200 includes a first power supply 210, a second power source 220, a switching circuit 230, a first reactor 240, a second reactor 250, and a capacitor 260.

The first power supply 210 and the second power source 220 are, for example, secondary batteries capable of charging and discharging. The positive terminal of the first power supply 210 is connected to a first node N1, and the negative terminal is connected to a second node N2 through the first reactor 240. The positive terminal of the second power source 220 is connected to a third node N3 through the second reactor 250, and the negative terminal is connected to a fourth node N4. The first power supply 210 and the second power source 220 are the same power supply, and the voltage provided by the first power supply 210 is equal to (or approximately equal to) the voltage provided by the second power source 220.

The switching circuit 230 is an equivalent circuit of the semiconductor module 100 shown in FIG. 1. A first switching element Q1, a second switching element Q2, and a third switching element Q3 included in the switching circuit 230 are respectively disposed in the first switch element area 110, the second switch element area 120, and the third switch element area 130 of the semiconductor module 100. As shown in FIG. 2, the first switching element Q1, the second switching element Q2, and the third switching element Q3 are sequentially connected in series. Under the control of a control signal Sct, the switching circuit 230 may be configured to switch the connection state of the first power supply 210, the second power source 220, and the electrical load.

The first switching element Q1 has a first metal semiconductor field effect transistor chip M1. The second switching element Q2 has an Insulated Gate Bipolar Transistor (IGBT) chip M21 and a second metal semiconductor field effect transistor chip M22 connected in parallel. The third switching element Q3 has a third metal semiconductor field effect transistor chip M3. The first metal semiconductor field effect transistor chip M1 may be implemented, for example, by the silicon carbide chip C1 in the first switch element area 110 shown in FIG. 1. The IGBT chip M21 and the second metal semiconductor field effect transistor chip M22 may be implemented, for example, by the IGBT chip C2 and the silicon carbide chip C1 in the second switch element area 120 shown in FIG. 1, respectively. The third metal semiconductor field effect transistor chip M3 may be implemented, for example, by the silicon carbide chip C1 in the third switch element area 130 shown in FIG. 1. The second metal semiconductor field effect transistor chip M22 (silicon carbide chip C1) of the second switching element Q2 is configured to be point-symmetric or line-symmetric with reference to the IGBT chip M21 (IGBT chip C2). The first switch element area 110 and the third switch element area 130 are disposed to be adjacent to the IGBT chip M21 of the second switching element Q2.

Furthermore, in one embodiment, the area of the second metal semiconductor field effect transistor chip M22 of the second switching element Q2 may be the same as the areas of the first metal semiconductor field effect transistor chip M1 of the first switching element Q1 and the third metal semiconductor field effect transistor chip M3 of the third switching element Q3.

In FIG. 2, the first switching element Q1 is connected between the first node N1 and the third node N3, and the second switching element Q2 is connected between the second node N2 and the third node N3. The third switching element Q3 is connected between the second node N2 and the fourth node N4. The first metal semiconductor field effect transistor chip M1 and the third metal semiconductor field effect transistor chip M3 are configured in a manner of sandwiching the second switching element Q2.

The first reactor 240 is disposed between the first power supply 210 and the second node N2. The second reactor 250 is disposed between the second power source 220 and the third node N3. The capacitor 260 is disposed between the first node N1 and the fourth node N4, and is configured to smooth the current output from the power supply 200.

Through the above structure, the semiconductor module 100 uses the IGBT chip C2 to ensure current capacity and may reduce cost.

In one embodiment, the IGBT chip M21 of the second switching element Q2 includes a temperature detection part for detecting component temperature, thereby may replace a conventional thermistor. Furthermore, since the IGBT chip C2 in FIG. 1 is placed at the center of the left and right silicon carbide chips C1, temperature may be detected uniformly.

The following embodiments explain the operation methods of the semiconductor module under different situations.

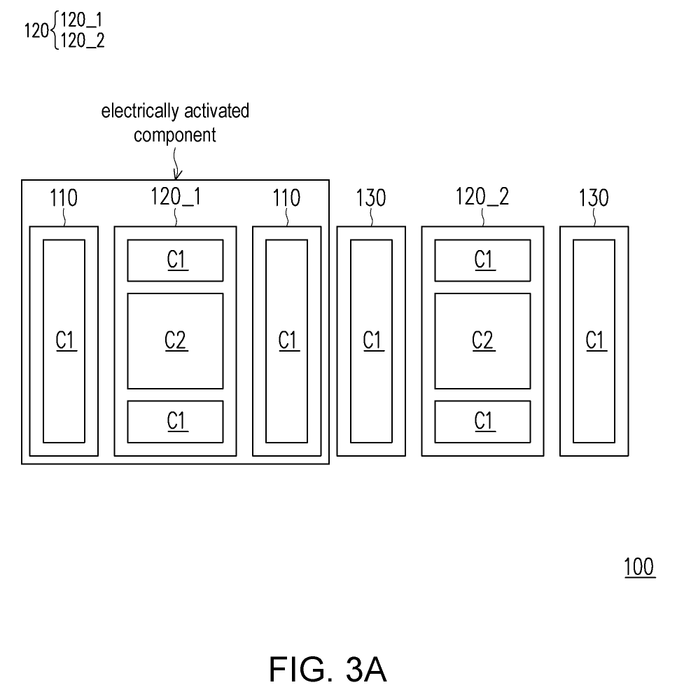

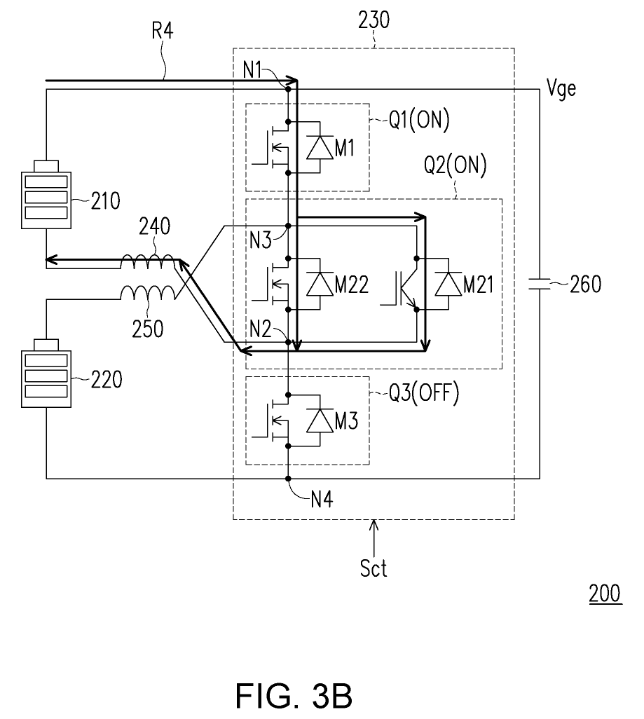

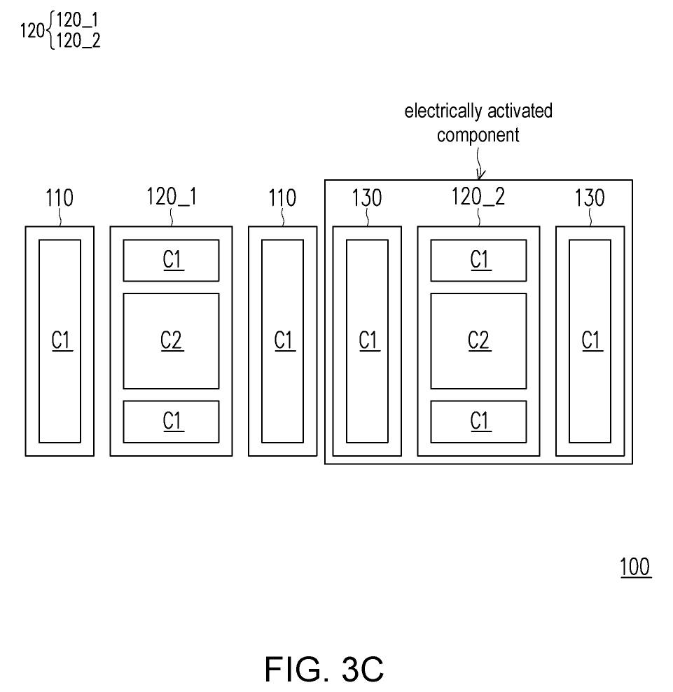

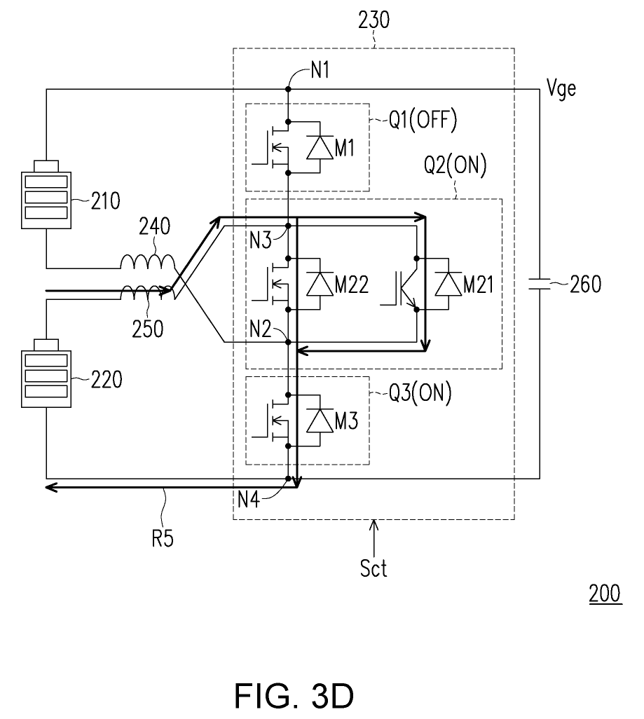

FIG. 3A to FIG. 3D show operation diagrams of the semiconductor module when the power supply enters a heat generation mode (belonging to low efficiency operation) according to an embodiment of the disclosure. In the situation where the power supply 200 enters the first heat generation mode, the components in the first switch element area 110 and the split area 120_1 of the second switch element area 120 in FIG. 3A may be set as electrically activated components. That is, the first heat generation mode may cause the split area 120_1 to conduct. At this time, as shown in FIG. 3B, the first heat generation mode may cause the first switching element Q1 and the second switching element Q2 to conduct, and the third switching element Q3 to be turned off, thereby generating a current path R4. In FIG. 3B, the current path R4 starts from the positive terminal of the first power supply 210, sequentially passes through the first node N1, the first switching element Q1, the third node N3, the second switching element Q2, the second node N2, and the first reactor 240, and finally returns to the negative terminal of the first power supply 210.

In the situation where the power supply 200 enters the second heat generation mode, the components in the third switch element area 130 and the split area 120_2 of the second switch element area 120 in FIG. 3C may be set as electrically activated components. That is, the second heat generation mode may cause the split area 120_2 to conduct. At this time, as shown in FIG. 3D, the second heat generation mode may cause the second switching element Q2 and the third switching element Q3 to conduct, and the first switching element Q1 to be turned off, thereby generating a current path R5. In FIG. 3D, the current path R5 starts from the positive terminal of the second power source 220, sequentially passes through the second reactor 250, the third node N3, the second switching element Q2, the second node N2, the third switching element Q3, and the fourth node N4, and finally returns to the negative terminal of the second power source 220.

Through the above structure, when operating at high efficiency, the distance between conducting chips may be increased to avoid thermal interference and make cooling easier, reducing power consumption of the power supply and operating with high efficiency. When operating at low efficiency, the distance between conducting chips may be reduced, causing temperature rise due to thermal interference and higher power consumption.

Through configuring the second switching element Q2 with the IGBT chip M21 and the second metal semiconductor field effect transistor chip M22 connected in parallel, the efficiency during general operation does not differ much compared to previous technical solutions, but when the power supply 200 enters heat generation mode (belonging to low efficiency operation), the component may be used as a heating element in situations where heat is needed by increasing the power consumption of the power supply.

In summary, the semiconductor module of the disclosure may use IGBT chips to ensure current capacity, and may simultaneously possess both high efficiency and low efficiency operation modes, and grasp the temperature of the entire chip through the temperature detection part in the IGBT chip, achieving the purpose of cost reduction, and further helping energy efficiency.

Finally, it should be explained that the foregoing embodiments are merely used to explain the technical solutions of the disclosure, and the embodiments are not limitations of the disclosure. Although the disclosure has been described in detail with reference to the foregoing embodiments, ordinary skilled persons in the art should understand that, they may still modify the technical solutions recorded in the foregoing embodiments, or perform equivalent substitutions for some or all of the technical characteristics thereof; and these modifications or substitutions do not cause the essence of the corresponding technical solutions to depart from the scope of the technical solutions of the embodiments of the disclosure.

What is claimed is:

1. A semiconductor module, comprising:
a first switch element area, a second switch element area, and a third switch element area, wherein the first switch element area and the third switch element area are configured in a manner of sandwiching the second switch element area,
a first switching element, a second switching element, and a third switching element are respectively disposed in the first switch element area, the second switch element area, and the third switch element area, wherein the first switching element, the second switching element, and the third switching element are sequentially connected in series,
wherein the second switching element has a bipolar chip and a second unipolar chip connected in parallel.

2. The semiconductor module according to claim 1, wherein the first switching element and the third switching element respectively have a first unipolar chip and a third unipolar chip, wherein the first unipolar chip and the third unipolar chip are configured in a manner of sandwiching the second switching element.

3. The semiconductor module according to claim 1, wherein the second unipolar chip of the second switching element is configured to be point-symmetric or line-symmetric with reference to the bipolar chip.

4. The semiconductor module according to claim 1, wherein the first switch element area and the third switch element area are disposed to be adjacent to the bipolar chip of the second switching element.

5. The semiconductor module according to claim 1, wherein the bipolar chip of the second switching element comprises a temperature detection part for detecting component temperature.

6. The semiconductor module according to claim 1, wherein the second switch element area is divided into at least two split areas, wherein the first switch element area is configured to sandwich one of the at least two split areas, and the third switch element area is configured to sandwich the other one of the at least two split areas.

7. The semiconductor module according to claim 6, wherein the one and the other one of the at least two split areas respectively have independent gate drive circuits.

8. The semiconductor module according to claim 1, wherein a first heat generation mode and a second heat generation mode are provided, wherein the first heat generation mode causes the first switching element and the second switching element to conduct, and the second heat generation mode causes the second switching element and the third switching element to conduct.

9. The semiconductor module according to claim 2, wherein a first heat generation mode and a second heat generation mode are provided, wherein the first heat generation mode causes the first switching element and the second switching element to conduct, and the second heat generation mode causes the second switching element and the third switching element to conduct.

10. The semiconductor module according to claim 3, wherein a first heat generation mode and a second heat generation mode are provided, wherein the first heat generation mode causes the first switching element and the second switching element to conduct, and the second heat generation mode causes the second switching element and the third switching element to conduct.

11. The semiconductor module according to claim 4, wherein a first heat generation mode and a second heat generation mode are provided, wherein the first heat generation mode causes the first switching element and the second switching element to conduct, and the second heat generation mode causes the second switching element and the third switching element to conduct.

12. The semiconductor module according to claim 5, wherein a first heat generation mode and a second heat generation mode are provided, wherein the first heat generation mode causes the first switching element and the second switching element to conduct, and the second heat generation mode causes the second switching element and the third switching element to conduct.

13. The semiconductor module according to claim 6, wherein a first heat generation mode and a second heat generation mode are provided, wherein the first heat generation mode causes the first switching element and the second switching element to conduct, and the second heat generation mode causes the second switching element and the third switching element to conduct,
in the first heat generation mode, the one of the at least two split areas is caused to conduct, and in the second heat generation mode, the other one of the at least two split areas is caused to conduct.

14. The semiconductor module according to claim 7, wherein a first heat generation mode and a second heat generation mode are provided, wherein the first heat generation mode causes the first switching element and the second switching element to conduct, and the second heat generation mode causes the second switching element and the third switching element to conduct,
in the first heat generation mode, the one of the at least two split areas is caused to conduct, and in the second heat generation mode, the other one of the at least two split areas is caused to conduct.
